(19) United States
(12) Patent Application Publication
(10) Pub. No.: US 2018/0190546 A1
(43) Pub. Date: Jul. 5, 2018

(54) METHOD FOR FORMING REPLACEMENT METAL GATE AND RELATED DEVICE

(71) Applicant: GLOBALFOUNDRIES Inc., Grand Cayman (KY)

(72) Inventors: Xusheng WU, Ballston Lake, NY (US); Haiting WANG, Clifton Park, NY (US)

(21) Appl. No.: 15/393,488

(22) Filed: Dec. 29, 2016

(51) Int. Cl. H01L 21/8238; H01L 21/28; H01L 29/66; H01L 27/092; H01L 29/49

(52) U.S. Cl. CPC H01L 21/823842; H01L 21/28088; H01L 29/4966; H01L 27/092; H01L 29/66545

(57) ABSTRACT

A method for eliminating line voids during RMG processing and the resulting device are provided. Embodiments include forming dummy gates over PFET and NFET regions of a substrate, each dummy gate having spacers at opposite sides, and an ILD filling spaces between spacers; removing dummy gate material from the gates, forming a cavity between each pair of spacers; forming a high-k dielectric layer over the ILD and spacers and in the cavities; forming a metal capping layer over the high-k dielectric layer; forming a first work function metal layer over the metal capping layer; removing the first work function metal layer from the PFET region; forming a second work function metal layer over the metal capping layer in the PFET region and over the first work function metal layer in the NFET region; and forming a metal layer over the second work function metal layer, filling the cavities.

### TECHNICAL FIELD

The present disclosure relates to semiconductor fabrication. In particular, the present disclosure relates to replacement metal gates (RMGs) in semiconductor device fabrication in the 14 nanometer (nm) technology node and beyond.

### BACKGROUND

In current semiconductor processing, as gate dimensions continue to get smaller, line voids can form during metal gate fill which lead to undesirable device performance or failure. With current RMG processing in the 14 nm technology node, line voids can occur in p-channel field-effect transistor (PFET) regions of a substrate due to insufficient gap fill margins. In particular, with current RMG processing, the n-channel field effect transistor (NFET) work function metal, such as titanium aluminum carbide (TiAlC), is not completely covered by subsequent barrier and gate fill metals in the PFET metal gate, leaving a line void. Moreover, without the protection of the barrier metal and gate fill metal in the line void, the TiAlC is left exposed and is etched away during chemical mechanical polishing (CMP) and in-situ dilute hydrofluoric (DHF)/ammonium hydroxide (NH₄OH) cleaning, which results in a defect. Moreover, with conventional RMG processing, the high dielectric constant (high-k) dielectric layer is undesirably exposed and damaged during annealing and patterning steps, which reduces reliability of the device.

A need therefore exists for methodology enabling mitigation of gate line voids and effective improvement of gate fill requirements, minimized high-k dielectric layer exposure and effective improvement in device reliability, and the resulting device.

### SUMMARY

An aspect of the present disclosure is a method that substantially eliminates line void defects during RMG processing and improves device performance. Another aspect includes protecting high-k dielectric material during PFET patterning to prevent high-k dielectric damage.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming dummy gates over PFET and n-channel field-effect transistor (NFET) regions of a substrate, each dummy gate having spacers formed on opposite sides of the dummy gate, and an interlayer dielectric (ILD) over source/drain (S/D) regions formed in the substrate, filling spaces between the spacers; removing dummy gate material from the gates, forming a cavity between each pair spacers; forming a high-k dielectric layer over the ILD and spacers and in the cavities; forming a metal capping layer over the high-k dielectric layer; forming a first work function metal layer over the metal capping layer; removing the first work function metal layer from the PFET region; forming a second work function metal layer over the metal capping layer in the PFET region and over the first work function metal layer in the NFET region; and forming a metal layer over the second work function metal layer, filling the cavities and forming RMGs.

Aspects of the present disclosure include planarizing down to an upper surface of the ILD, removing excess metal layer, first and second work function metal layers and high-k dielectric layer and exposing upper surfaces of the side spacers and ILD. Other aspects include planarizing with CMP. Still further aspects include forming the metal capping layer of titanium nitride (TiN). Certain aspects include forming the first work function metal layer of TiAlC. Other aspects include the TiAlC being for an n-type device. Certain aspects include forming the second work function metal layer of TiN for a p-type device. Yet further aspects include forming the metal layer of tungsten (W), aluminum (Al), W alloys, or Al alloys. Other aspects include forming the metal layer in a cavity over the PFET region, wherein the cavity is wider in the PFET region than the NFET region. In certain aspects, the dummy gates are formed of polysilicon; and the polysilicon is removed to form the cavities between the spacers.

Another aspect of the present disclosure is a device including an ILD formed over a substrate with cavities formed over PFET and NFET regions of the substrate and S/D regions formed in the substrate at opposite sides of each cavity; spacers on sidewalls of each cavity; RMGs between the spacers in each cavity, wherein each RMG includes: a high-k dielectric layer on side and bottom surfaces of the cavity; a metal capping layer over the high-k dielectric layer; a first work function metal layer over the metal capping layer in the NFET region; a second work function metal layer over the metal capping layer in the PFET region and over the first work function metal layer in the NFET region; and a metal layer over the second work function metal layer.

Aspects of the present disclosure include the metal capping layer including TiN. Other aspects include the first work function metal layer including TiAlC. Still further aspects include the TiAlC being for an n-type device. Certain aspects include the second work function metal layer including TiN for a p-type device. Other aspects include the metal layer including W, Al, W alloys, or Al alloys. Certain aspects include the metal layer being wider in the PFET region than the NFET region.

Yet another aspect of the present disclosure includes a method including forming polysilicon dummy gates over PFET and NFET regions of a substrate, each polysilicon dummy gate having spacers formed on opposite sides of the polysilicon dummy gate, and an ILD over S/D regions formed in the substrate, filling spaces between the spacers; removing the dummy gates, forming cavities between the spacers; forming a high-k dielectric layer over the ILD and spacers and in the cavities; forming a TiN capping layer over the high-k dielectric layer; forming TiAlC n-type work function layer over the TiN capping layer; removing the TiAlC n-type work function layer from the PFET region; forming a TiN p-type work function layer over the TiN capping layer in the PFET region and over the TiAlC n-type work function layer in the NFET region; and forming a metal layer filling the cavities, forming RMGs.

Aspects include forming the metal layer in an opening over the PFET region, wherein a width of the metal layer over the PFET region is larger than a width of the metal layer over the NFET region. Additional aspects include forming the metal layer of W, Al, W alloys, or Al alloys.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1 through 9 schematically illustrate a semiconductor fabrication process, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of line voids and exposure of high-k dielectric material during RMG processing. In accordance with embodiments of the present disclosure, a novel method and resulting device are provided which eliminate RMG gap fill voids and improve device performance.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

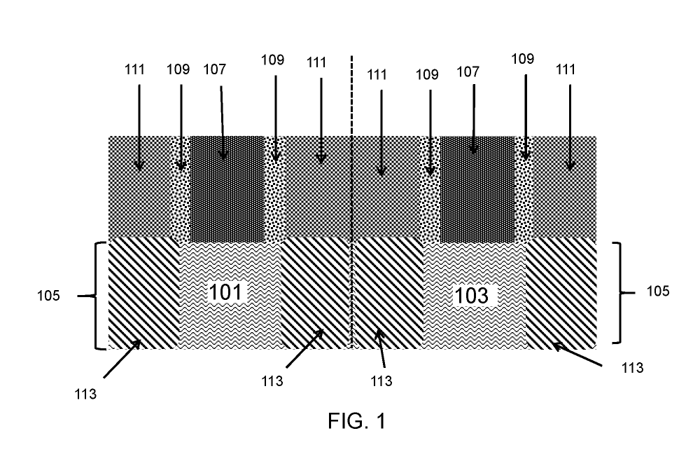

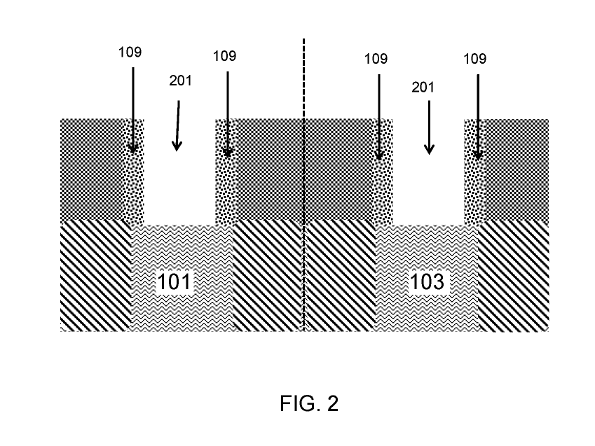

Adverting to FIG. 1, dummy gates are formed over PFET regions 101 and NFET regions 103 of a substrate 105. Each dummy gate has polysilicon material 107 and spacers 109 formed on opposite sides of the polysilicon material 107. An ILD 111 is formed over S/D regions 113 formed in the substrate 105, filling spaces between the spacers 109. A gate oxide liner (not shown) can be formed under each dummy gate. As shown in FIG. 2, the polysilicon material 107 is removed from the dummy gate to form a cavity 201 between each pair of spacers 109.

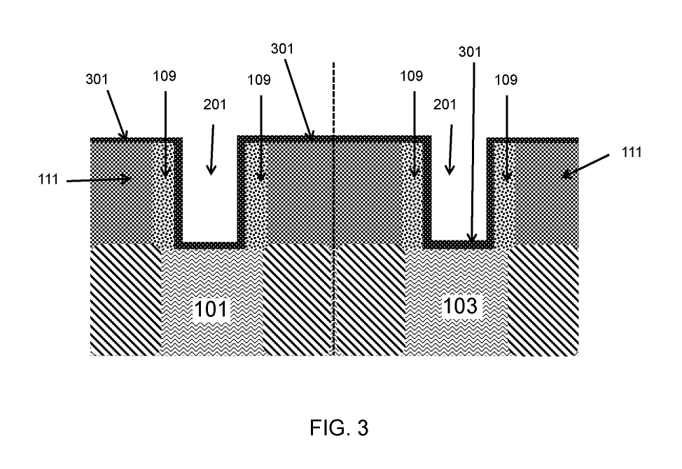

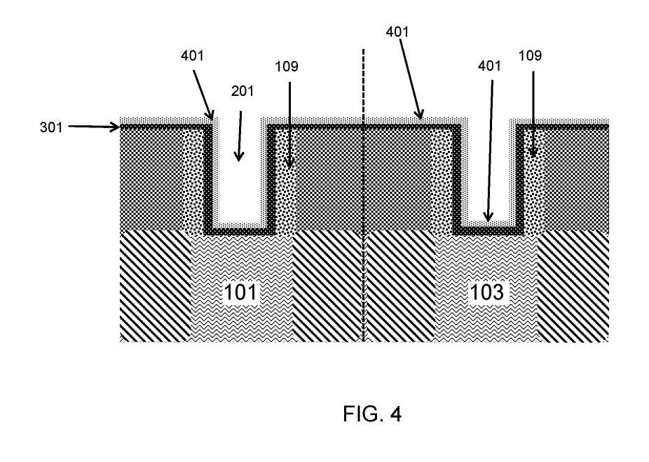

Adverting to FIG. 3, a high-k dielectric layer 301 is deposited over the ILD 111 and spacers 109 and on side and bottom surfaces of each cavity 201. The high-k dielectric layer 301 is formed to a thickness of 1 to 5 nm. In FIG. 4, a metal capping layer 401 is deposited over the high-k dielectric layer 301. The metal capping layer 401 is formed of a metal such as TiN and is formed to a thickness of 1 to 5 nm.

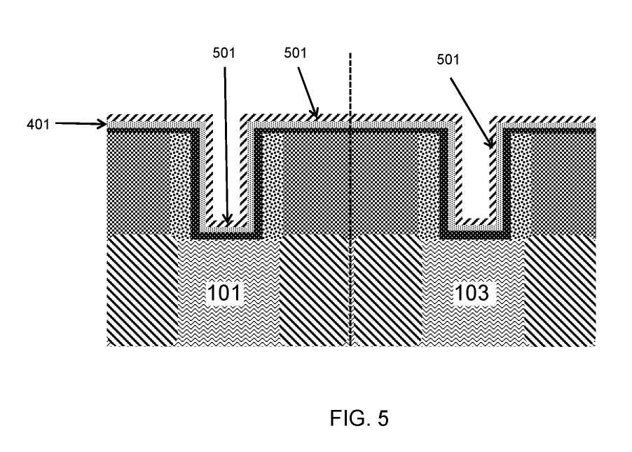

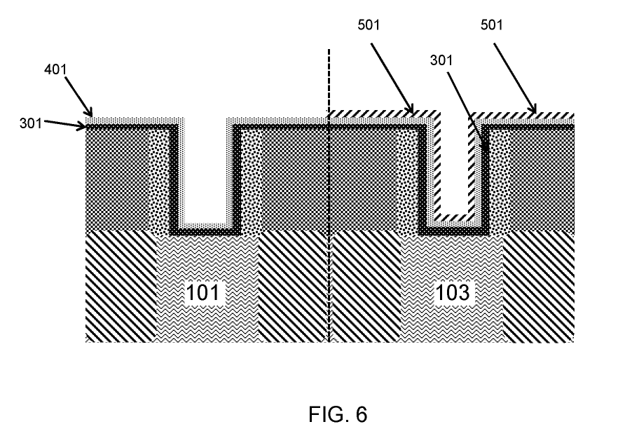

Adverting to FIG. 5, a work function metal layer 501 is deposited over the metal capping layer 401, for example to a thickness of 1 to 10 nm. The work function metal layer 501 is formed of a work function metal for a n-type device, for example TiAlC. As shown in FIG. 6, a patterning is performed to etch away the work function metal layer 501 over the PFET region 101. The work function metal layer 501 remains over the NFET region 103. Since the high-k dielectric layer 301 is covered by the metal capping layer 401, this patterning etch does not damage the high-k dielectric layer 301. Accordingly, the current process is an improvement over conventional RMG processing, which exposes the high-k dielectric layer to etching. Device reliability is improved with the protection of the high-k dielectric layer 301.

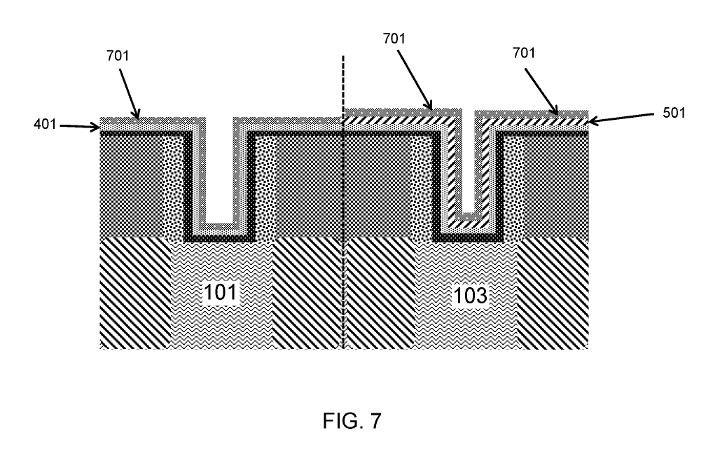

Adverting to FIG. 7, a second work function metal layer 701 is deposited over the metal capping layer 401 in the PFET region 101 and over the work function metal layer 501 in the NFET region 103. The second work function metal layer 701 is formed to a thickness of 1 to 10 nm. The second work function metal layer is formed of a work function metal for a p-type device, for example TiN.

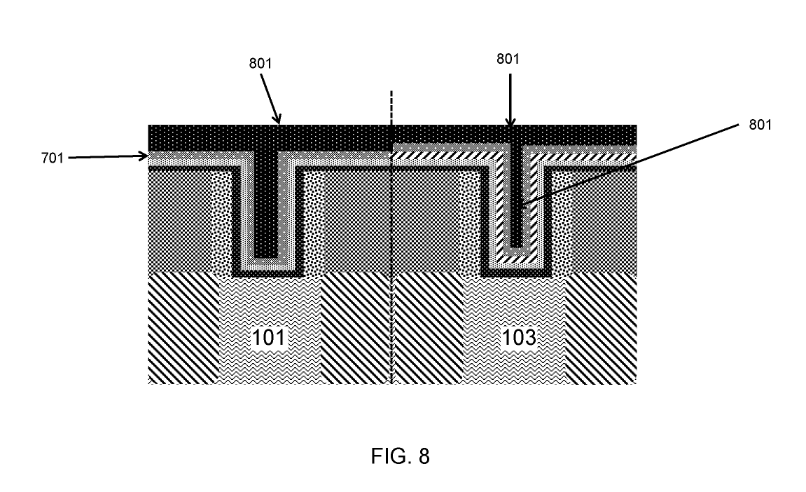

Adverting to FIG. 8, a metal layer 801, e.g. W, Al, W alloys, or Al alloys, is deposited over the second work function metal layer 701 and fills the remainder of each cavity 201. Since the cavity 201 over the PFET region 101 after the depositions prior to the metal layer 801 is wider than the cavity 201 in the NFET region 103, the PFET has more space for the metal fill, thereby reducing the gate resistance.

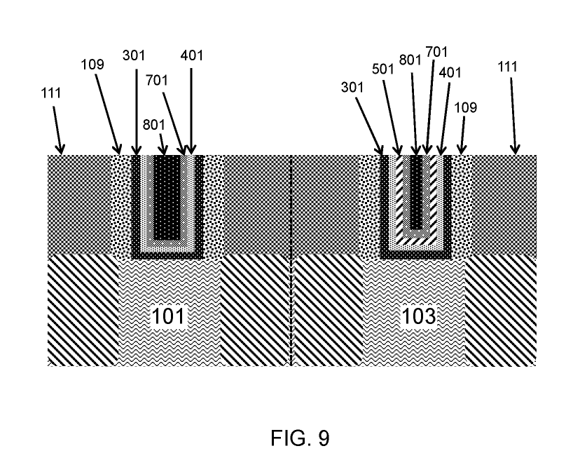

In FIG. 9, a planarization step, such as CMP is performed for planarizing down to an upper surface of the ILD 111, removing excess metal layer 801, work function metal layers 501 and 701 and high-k dielectric layer 301 and exposing upper surfaces of the side spacers 109 and ILD 111 and forming the replacement metal gates (RMG) in both the PFET region 101 and NFET region 103. Additional RMG manufacturing follows using conventional processing steps.

The embodiments of the present disclosure can achieve several technical effects, including improving gapfill and minimizing high-k dielectric layer exposure, thereby effectively improving device reliability and reducing defects which can result in electrical shorts. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for advanced technology nodes, such as the 14 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming dummy gates over p-channel field-effect transistor (PFET) and n-channel field-effect transistor (NFET) regions of a substrate, each dummy gate having spacers formed on opposite sides of the dummy gate, and an interlayer dielectric (ILD) over source/drain (S/D) regions formed in the substrate, filling spaces between the spacers;
removing dummy gate material from the gates, forming a cavity between each pair of spacers;
forming a high-k dielectric layer over the ILD and spacers and in the cavities;
forming a metal capping layer over the high-k dielectric layer;
forming a first work function metal layer over the metal capping layer, the first work function metal layer comprising aluminum-doped titanium carbide (TiAlC) for a n-type device;
removing the first work function metal layer from the PFET region;
forming a second work function metal layer over the metal capping layer in the PFET region and over the first work function metal layer in the NFET region; and
forming a metal layer over the second work function metal layer, filling the cavities and forming replacement metal gates (RMG).

2. The method according to claim 1, further comprising:
planarizing down to an upper surface of the ILD, removing excess metal layer, first and second work function metal layers and high-k dielectric layer and exposing upper surfaces of the side spacers and ILD.

3. The method according to claim 2, comprising:
planarizing with chemical mechanical polishing (CMP).

4. The method according to claim 1, comprising forming the metal capping layer of titanium nitride (TiN).

5. (canceled)

6. (canceled)

7. The method according to claim 1, comprising:
forming the second work function metal layer of TiN for a p-type device.

8. The method according to claim 1, comprising:
forming the metal layer of tungsten (W), aluminum (Al) or alloys thereof.

9. The method according to claim 8, comprising:
forming the metal layer in a cavity over the PFET region, wherein the cavity is wider in the PFET region than the NFET region.

10. The method according to claim 1, comprising:
forming the dummy gates of polysilicon; and
removing the polysilicon to form the cavities between the spacers.

11. A device comprising:
an interlayer dielectric (ILD) formed over a substrate with cavities formed over p-channel field-effect transistor (PFET) and n-channel field-effect transistor (NFET) regions of the substrate and source/drain (S/D) regions formed in the substrate at opposite sides of each cavity;
spacers on sidewalls of each cavity;
replacement metal gates (RMG) between the spacers in each cavity,
wherein each RMG comprises:
a high-k dielectric layer on side and bottom surfaces of the cavity;
a metal capping layer over the high-k dielectric layer;
a first work function metal layer over the metal capping layer in the NFET region;
a second work function metal layer over the metal capping layer in the PFET region and over the first work function metal layer in the NFET region; and
a metal layer over the second work function metal layer.

12. The device according to claim 11, wherein the metal capping layer comprises titanium nitride (TiN).

13. The device according to claim 11, wherein the first work function metal layer comprises aluminum-doped titanium carbide (TiAlC).

14. The device according to claim 13, wherein the TiAlC is for an n-type device.

15. The device according to claim 11, wherein the second work function metal layer comprises TiN for a p-type device.

16. The device according to claim 11, wherein the metal layer comprises tungsten (W), aluminum (Al) or alloys thereof.

17. The device according to claim 16, wherein the metal layer is wider in the PFET region than the NFET region.

18. A method comprising:
forming polysilicon dummy gates over p-channel field-effect transistor (PFET) and re-channel field-effect transistor (NFET) regions of a substrate, each polysilicon dummy gate having spacers formed on opposite sides of the polysilicon dummy gate, and an interlayer dielectric (ILD) over source/drain (S/D) regions formed in the substrate, filling spaces between the spacers;
removing the dummy gates, forming cavities between the spacers;
forming a high-k dielectric layer over the ILD and spacers and in the cavities;
forming a titanium nitride (TiN) capping layer over the high-k dielectric layer;
forming an aluminum-doped titanium carbide (TiAlC) n-type work function layer over the TiN capping layer;
removing the TiAlC n-type work function layer from the PFET region;
forming a TiN p-type work function layer over the TiN capping layer in the PFET region and over the TiAlC n-type work function layer in the NFET region; and
forming metal layer filling the cavities, forming replacement metal gates (RMG).

19. The method according to claim 18, comprising:
forming the metal layer in an opening over the PFET region, wherein a width of the metal layer over the PFET region is larger than a width of the metal layer over the NFET region.

20. The method according to claim 19, comprising:
forming the metal layer of tungsten (W), aluminum (Al) or alloys thereof.
